(19) United States
(12) Patent Application Publication
(10) Pub. No.: US 2026/0371575 A1
(43) Pub. Date: Nov. 19, 2026

(54) SEMICONDUCTOR DEVICES WITH INSULATING STRUCTURE

(71) Applicant: Samsung Electronics Co., Ltd., Suwon-si (KR)

(72) Inventors: Cheonbae Kim, Suwon-si (KR); Joon Han, Suwon-si (KR); Woochoel Noh, Suwon-si (KR); Junwon Lee, Suwon-si (KR)

(21) Appl. No.: 19/427,321

(22) Filed: Dec. 19, 2025

(30) Foreign Application Priority Data
May 19, 2025 (KR) 10-2025-0064724

(51) Int. Cl. H10B 12/00; H10B 80/00; H10W 90/00; H10W 90/20

(52) U.S. Cl. CPC H10B 12/50; H10B 80/00; H10W 90/297; H10W 90/792

(57) ABSTRACT

A semiconductor device includes a peripheral circuit structure. The peripheral circuit structure includes: a first substrate including a first substrate region and a second substrate region having different conductivity types, wherein the first substrate comprises a first surface and a second surface opposing the first surface along a vertical direction; a trench isolation film extending in the vertical direction from the first surface of the first substrate toward the second surface of the first substrate; and an insulating structure extending in the vertical direction from the second surface of the first substrate toward the first surface of the first substrate. The insulating structure is in contact with each of the first substrate region and the second substrate region. The insulating structure is spaced apart from the trench isolation film.

### CROSS-REFERENCE TO RELATED APPLICATION

This application claims priority under 35 U.S.C. §119 to Korean Patent Application No. 10-2025-0064724, filed on May 19, 2025, in the Korean Intellectual Property Office, the entirety of which is incorporated by reference herein.

### BACKGROUND

In response to industrial advancements and consumer demands, high-performance semiconductor devices with large storage capacity are required. To improve the performance and storage capacity of semiconductor devices, semiconductor devices having a structure in which multiple semiconductor dies are stacked are widely used. Research on semiconductor devices of reduced size is being conducted in line with the trend of down-scaling semiconductor devices.

### SUMMARY

Some aspects of the present disclosure provide semiconductor devices with improved reliability, and methods of manufacturing the same. The advantages provided by the present disclosure are not limited to the foregoing, and others can be clearly understood by those skilled in the art from the description below.

According to some aspects of the present disclosure, there is provided a semiconductor device including a peripheral circuit structure, the peripheral circuit structure including a first substrate including a first substrate region and a second substrate region having different conductivity types, and including a first surface and a second surface opposite to the first surface, a trench isolation film extending in a vertical direction from the first surface of the first substrate toward the inside of each of the first substrate region and the second substrate region, and an insulating structure extending in the vertical direction from the second surface of the first substrate toward the inside of each of the first substrate region and the second substrate region, wherein the insulating structure is not in contact with the trench isolation film.

According to some aspects of the present disclosure, there is provided a semiconductor device including a memory cell structure, a peripheral circuit structure, and through vias electrically connecting the memory cell structure to the peripheral circuit structure, wherein the peripheral circuit structure includes a first substrate including a first substrate region and a second substrate region having different conductivity types, and including a first surface and a second surface opposite to the first surface, wherein the second substrate region includes an upper second substrate region arranged at the same vertical level as the first substrate region, and a lower second substrate region surrounding a lower portion of at least a part of the first substrate region at a lower vertical level than the first substrate region and the upper second substrate region, a trench isolation film extending in a vertical direction from the first surface of the first substrate toward the inside of each of the first substrate region and the upper second substrate region, a peripheral circuit transistor disposed on each of the first substrate region and the upper second substrate region, a peripheral circuit wiring layer electrically connected to the peripheral circuit transistor, and an insulating structure extending in the vertical direction from the second surface of the first substrate toward the inside of each of the first substrate region and the upper second substrate region, wherein the insulating structure is not in contact with the trench isolation film, and at least the part of the first substrate region is not in contact with the insulating structure.

According to some aspects of the present disclosure, there is provided a semiconductor device including a memory cell structure, a peripheral circuit structure disposed on the memory cell structure, and through vias electrically connecting the memory cell structure to the peripheral circuit structure, wherein the peripheral circuit structure includes a first substrate including a first substrate region and a second substrate region having different conductivity types, a peripheral circuit transistor disposed on the first substrate region and the second substrate region, a peripheral circuit wiring layer electrically connected to the peripheral circuit transistor, a trench isolation film extending in a vertical direction from the first surface of the first substrate toward the inside of each of the first substrate region and the second substrate region, and an insulating structure extending in the vertical direction toward the inside of each of the first substrate region and the second substrate region from a second surface opposite to the first surface of the first substrate, wherein one surface of the insulating structure is arranged at the same vertical level as the second surface of the first substrate, and a height of the insulating structure is less than a distance from the one surface of the insulation structure to the trench isolation film in the vertical direction.

### BRIEF DESCRIPTION OF THE DRAWINGS

FIG. 1A is a cross-sectional view of an example of a semiconductor device;

FIG. 1B is an enlarged cross-sectional view of portion EX1 of FIG. 1A;

FIG. 2A is a cross-sectional view of an example of a semiconductor device;

FIG. 2B is an enlarged cross-sectional view of portion EX2 of FIG. 2A;

FIG. 3A is a cross-sectional view of an example of a semiconductor device;

FIG. 3B is an enlarged cross-sectional view of portion EX3 of FIG. 3A;

FIG. 4A is a cross-sectional view of an example of a semiconductor device;

FIG. 4B is an enlarged cross-sectional view of portion EX4 of FIG. 4A;

FIGS. 5 to 9 are cross-sectional views illustrating an example of a method of manufacturing a semiconductor device; and

FIGS. 10 to 15 are cross-sectional views illustrating an example of a method of manufacturing a semiconductor device.

### DETAILED DESCRIPTION

Hereinafter, examples are described in detail with reference to the accompanying drawings. The same reference numerals are used for the same components in the drawings, and redundant descriptions thereof are omitted.

Specific examples are illustrated in the drawings and described in detail in the description. However, it should be understood that the scope of this disclosure is not limited to these specific examples but also includes all modifications, equivalents, or alternatives falling within the spirit and scope of the present disclosure.

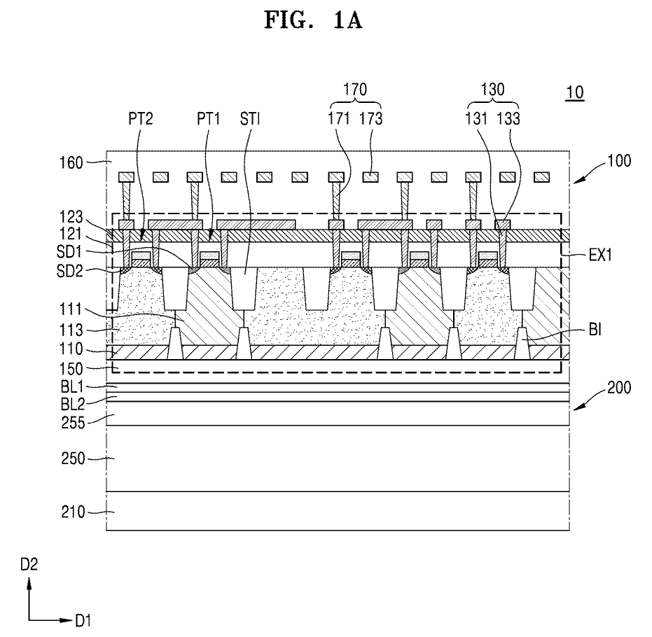

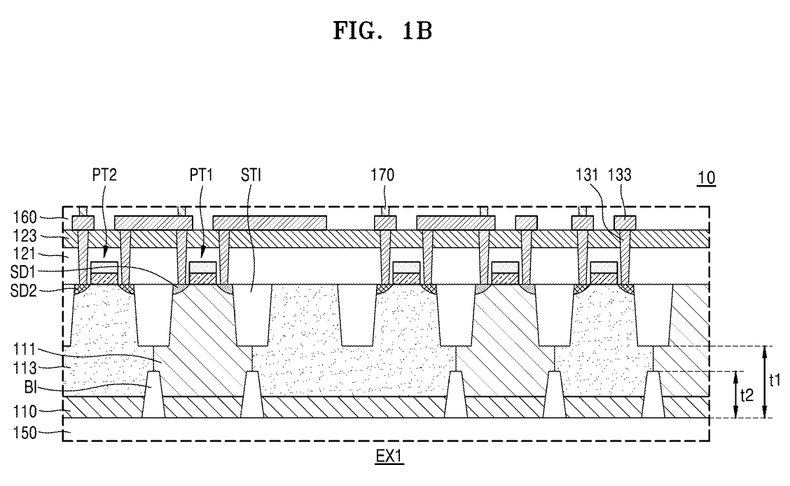

FIG. 1A is a cross-sectional view of an example of a semiconductor device 10. FIG. 1B is an enlarged cross-sectional view of portion EX1 of FIG. 1A.

Referring to FIGS. 1A and 1B, the semiconductor device 10 may include a peripheral circuit structure 100 and a memory cell structure 200. The peripheral circuit structure 100 may be stacked on top of the memory cell structure 200. The peripheral circuit structure 100 may be in contact with the memory cell structure 200 through bonding insulating layers BL1 and BL2.

The peripheral circuit structure 100 may include a core region or a peripheral circuit region of a dynamic random-access memory (DRAM) device, and the memory cell structure 200 may include an array region of volatile memory cells of the DRAM device. For example, the peripheral circuit structure 100 may include peripheral circuit transistors PT1 and PT2 for transmitting signals and/or power to memory cell transistors included in the memory cell structure 200.

The peripheral circuit structure 100 may include a first substrate 110 where a trench isolation film STI is formed.

The first substrate 110 may include a wafer including silicon (Si). In some implementations, the first substrate 110 may include a wafer including a semiconductor element, such as germanium (Ge), or a compound semiconductor, such as silicon carbide (SiC), gallium arsenide (GaAs), indium arsenide (InAs), or indium phosphide (InP).

The first substrate 110 may include a first substrate region 111 and a second substrate region 113. The first substrate region 111 and the second substrate region 113 may have different conductivity types. For example, the first substrate region 111 may include a p-well doped with p-type impurities, and the second substrate region 113 may include an n-well doped with n-type impurities. As another example, the first substrate region 111 may include a n-well doped with n-type impurities, and the second substrate region 113 may include a p-well doped with p-type impurities.

A first source/drain region SD1 may be formed in the first substrate region 111, and a second source/drain region SD2 may be formed in the second substrate region 113. The first source/drain region SD1 may constitute a portion of the first peripheral circuit transistor PT1 to be described below, and the second source/drain region SD2 may constitute a portion of the second peripheral circuit transistor PT2 to be described below.

An active region may be defined by the trench isolation film STI, which is an insulating region, in the first substrate 110. The trench isolation film STI may extend in a vertical direction D2 toward the inside of each of the first substrate region 111 and the second substrate region 113. The trench isolation film STI may be in contact with each of the first substrate region 111 and the second substrate region 113

In some implementations, the first peripheral circuit transistor PT1 and the second peripheral circuit transistor PT2 may be disposed on the first substrate 110. The first peripheral circuit transistor PT1 may be disposed on the first substrate region 111, and the second peripheral circuit transistor PT2 may be disposed on the second substrate region 113. In some implementations, each of the first peripheral circuit transistor PT1 and the second peripheral circuit transistor PT2 may be included in various circuits, such as a command decoder, a control logic, an address buffer, a row decoder, a column decoder, a sense amplifier, a data input/output circuit, and/or the like.

Each of the first peripheral circuit transistor PT1 and the second peripheral circuit transistor PT2 may include a gate dielectric film and a gate electrode stacked on the active region in this order. The gate dielectric film may be formed of at least one selected from silicon oxide, silicon nitride, silicon oxynitride, and a high dielectric material having a dielectric constant higher than that of silicon oxide. The gate electrode may include doped polysilicon, titanium nitride (TiN), titanium silicon nitride (TiSiN), tungsten (W), tungsten silicide (WSi), or a combination thereof. In some implementations, both sidewalls of the gate electrode may be covered with a gate spacer. The gate spacer may include silicon oxide, silicon nitride, or a combination thereof.

Each of the first peripheral circuit transistor PT1 and the second peripheral circuit transistor PT2 may include, for example, a gate-all around field effect transistor (GAAFET), a multi-bridge channel field effect transistor (MBCFET), or a fin field effect transistor (FinFET). Other transistor types are also within the scope of this disclosure.

The first peripheral circuit insulating layer 121 may cover the first peripheral circuit transistor PT1 and the second peripheral circuit transistor PT2. An interlayer insulating layer 123 may be disposed on the first peripheral circuit insulating layer 121. The first peripheral circuit insulating layer 121 may be made of, for example, an oxide. The interlayer insulating layer 123 may be made of, for example, a nitride (e.g., silicon nitride).

A first peripheral circuit wiring layer 130 may be disposed on the first substrate 110. The first peripheral circuit wiring layer 130 may include a first peripheral circuit via 131 and a first peripheral circuit line 133. The first peripheral circuit via 131 may penetrate the first peripheral circuit insulating layer 121 and the interlayer insulating layer 123 in the vertical direction D2. The first peripheral circuit via 131 may be in contact with the first source/drain region SD1 and the second source/drain region SD2. The first peripheral circuit via 131 may be connected to each of the first peripheral circuit transistor PT1 and the second peripheral circuit transistor PT2. The first peripheral circuit line 133 may be disposed on the interlayer insulating layer 123. The first peripheral circuit line 133 may be electrically connected to each of the first peripheral circuit transistor PT1 and the second peripheral circuit transistor PT2 through the first peripheral circuit via 131.

In some implementations, a second peripheral circuit wiring layer 170 and a second peripheral circuit insulating layer 160 may be disposed on the interlayer insulating layer 123. The second peripheral circuit insulating layer 160 may cover the top surface of the interlayer insulating layer 123 and the second peripheral circuit wiring layer 170. The second peripheral circuit insulating layer 160 may be made of, for example, an oxide. The second peripheral circuit wiring layer 170 may include a second peripheral circuit via 171 and a second peripheral circuit line 173. The second peripheral circuit via 171 may be in contact with the first peripheral circuit line 133. The second peripheral circuit line 173 may be electrically connected to the first peripheral circuit line 133 through the second peripheral circuit via 171.

The first peripheral circuit wiring layer 130 and the second peripheral circuit wiring layer 170 may be formed of, for example, a copper layer, an aluminum layer, or a tungsten layer.

Each of a plurality of insulating structures BI may be aligned in the vertical direction D2 at the boundary between the first substrate region 111 and the second substrate region 113. The bottom surface of the insulating structure BI may be arranged at the same vertical level as the bottom surface of the first substrate 110. The top surface of the insulating structure BI may be arranged between a vertical level where the bottom surfaces of the first and second substrate regions 111 and 113 are arranged and a vertical level where the bottom surface of the trench isolation film STI is arranged. That is, the top surface of the insulating structure BI may be arranged at a higher vertical level than the bottom surfaces of the first and second substrate regions 111 and 113 and may be arranged at a lower vertical level than the bottom surface of the trench isolation film STI.

Referring to FIG. 1B, a second length t2 that is a height of the insulating structure BI in the vertical direction D2 may be less than a first length t1 that is a length from the bottom surface of the first substrate 110 to the bottom surface of the trench isolation film STI. Although the plurality of insulating structures BI are shown in FIGS. 1A and 1B to have the same height, this is only an example, and their heights are not limited thereto. For example, the top surfaces of each of the plurality of insulating structures BI may be arranged at different vertical levels within a range that is greater than the vertical level of the bottom surfaces of the first and second substrate regions 111 and 113 and less than the vertical level of the bottom surface of the trench isolation film STI. The bottom surfaces of the plurality of insulating structures BI may be coplanar with the bottom surface of the first substrate 110.

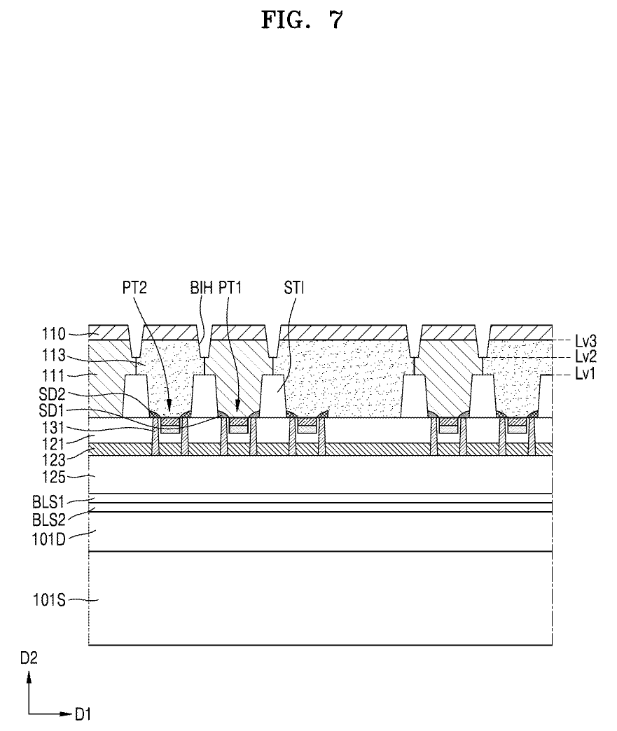

The plurality of insulating structures BI may have a tapered shape in which a cross-sectional area of the bottom surface is greater than that of the top surface, gradually narrowing toward the top surface. This may include a profile obtained by flipping the first substrate 110 so that the bottom surface of the first substrate 110 is arranged at the top before performing the process of forming a plurality of insulating structure holes BIH (see FIG. 7). For example, the cross-sectional area of the trench isolation film STI may increase in a direction away from the bottom surface of the first substrate 110, while the cross-sectional area of the plurality of insulating structures BI may decrease in the direction away from the bottom surface of the first substrate 110.

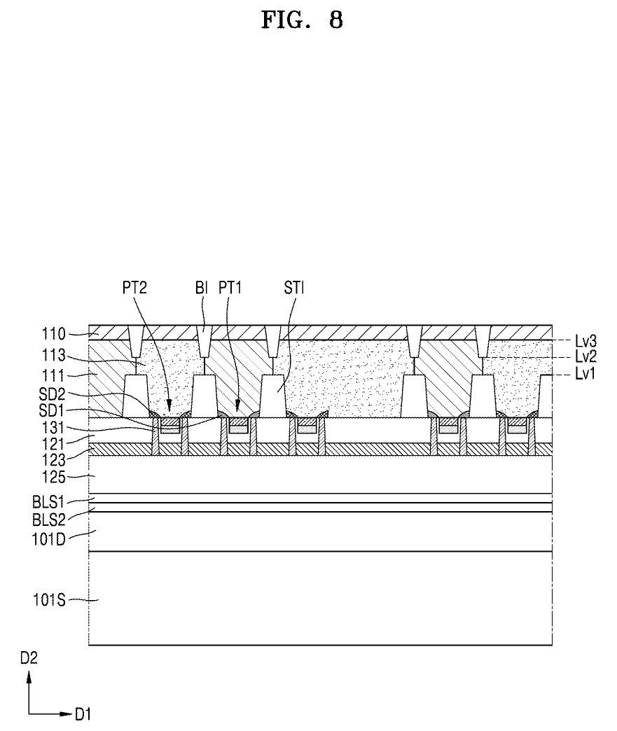

In some implementations, the insulating structure BI may be arranged between the first substrate region 111 and the second substrate region 113 to prevent the leakage of current between the first substrate region 111 and the second surface region 113. For example, in the absence of the insulating structure BI, to prevent the leakage of current between the first substrate region 111 and the second substrate region 113, the first substrate 110 may be flipped so that the bottom surface of the first substrate 110 is arranged at the top, then the bottom surface of the first substrate 110 may be thinned to a certain thickness, and then a recess may be formed in the first substrate 110 until the trench isolation film STI was exposed to form an insulating structure. Although the resulting comparative structure may reduce leakage of current between wells, the characteristics of the first and/or second peripheral circuit transistors PT1 and/or PT2 may be deteriorated by the insulating structure formed through the foregoing process. Thus, the semiconductor device 10 shown in FIGS. 1A and 1B may include the insulating structure BI to a depth not in contact with the trench isolation film STI (see FIGS. 7 and 8) to reduce the difficulty of the process of forming the insulating structure BI and prevent the deterioration of the electrical characteristics of the first and/or second peripheral circuit transistor TR1 and/or TR2.

In some implementations, the insulating structure BI may include an insulating material. For example, the insulating structure BI may include silicon oxide, but the material thereof is not limited to silicon oxide.

The memory cell structure 200 may include a second substrate 210. The material constituting the second substrate 210 may be substantially the same as the material constituting the first substrate 110 described above. Thus, a detailed description thereof is omitted.

A laminated structure 250 may be disposed on the second substrate 210. The laminated structure 250 may include a plurality of insulating layers and a plurality of conductive lines that are alternately stacked. In some implementations, each of the plurality of insulating layers and the plurality of conductive lines may extend in a horizontal direction D1. The plurality of conductive lines may function as word lines of the memory cell structure 200.

In some implementations, the laminated structure 250 may further include a plurality of channel regions spaced apart from each other in the vertical direction D2. In addition, a cell wiring layer may be connected to the conductive line located at the top. The cell wiring layer may be formed of, for example, a copper layer, an aluminum layer, or a tungsten layer.

The cell transistor included in the memory cell structure 200 may include, for example, a buried cell array transistor (BACT), a vertical cell transistor (VCT), or a three-dimensional (3D) stacked transistor.

In the semiconductor device 10, the peripheral circuit structure 100 and the memory cell structure 200 may form a bonding structure. In some implementations, the peripheral circuit structure 100 may be bonded to the memory cell structure 200 using a heat treatment process. The heat treatment process may be performed at a temperature where bonding coupling is formed between the insulating material of the peripheral circuit structure 100 and the insulating material of the memory cell structure 200. Accordingly, the first bonding insulating layer BL1 and the second bonding insulating layer BL2 may be bonded between the peripheral circuit structure 100 and the memory cell structure 200.

In some implementations, the semiconductor device 10 may further include a through via that electrically connects the peripheral circuit structure 100 to the memory cell structure 200. The through via may penetrate the interlayer insulating layer 123, the first peripheral circuit insulating layer 121, a lower insulating layer 150, the first bonding insulating layer BL1, the second bonding insulating layer BL2, and a second upper insulating layer 255 in the vertical direction D2. The through via may include, for example, a through silicon via. A plurality of through vias may be spaced apart from each other to electrically connect the peripheral circuit structure 100 to the memory cell structure 200.

As described above, the semiconductor device 10 separates the boundary between the first substrate region 111 and the second substrate region 113 such that, in some implementations, the insulating structure BI is not in contact with the trench isolation film STI (e.g., the insulating structure BI is spaced apart from the trench isolation film STI), thereby effectively preventing the leakage of current between wells without affecting the electrical reliability of the first and/or second peripheral circuit transistors PT1 and/or PT2. In addition, since the insulating structure BI is not formed deeper than necessary, a process (see FIG. 8) of filling the insulating structure hole BIH (see FIG. 7) with the insulating structure BI may be relatively easy.

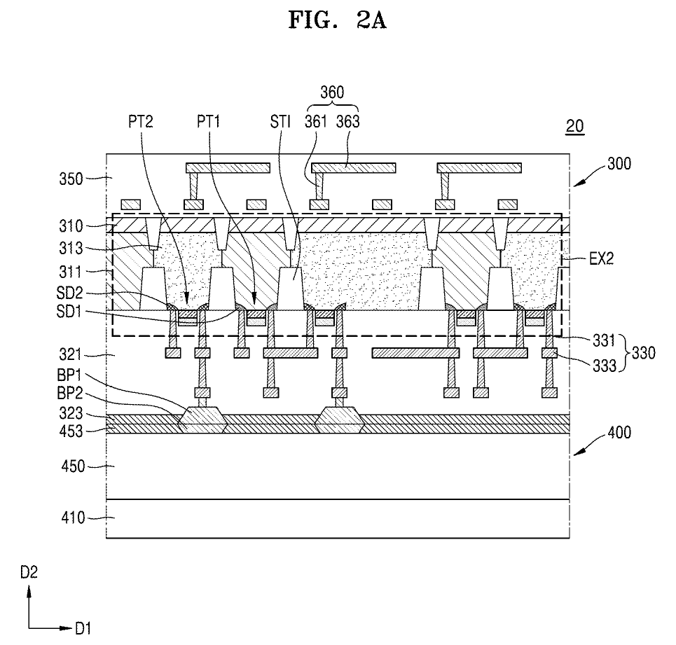

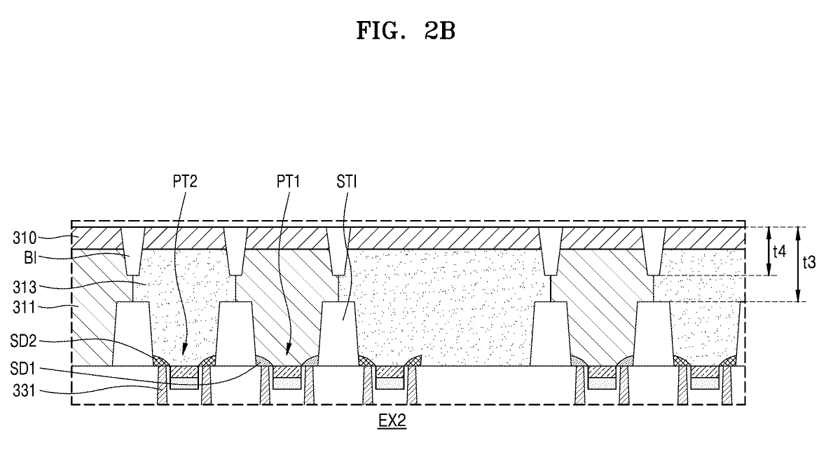

FIG. 2A is a cross-sectional view of another example of a semiconductor device 20. FIG. 2B is an enlarged cross-sectional view of portion EX2 of FIG. 2A.

Referring to FIGS. 2A and 2B, the semiconductor device 20 may include a peripheral circuit structure 300 and a memory cell structure 400. The peripheral circuit structure 300 may be stacked on top of the memory cell structure 400. The peripheral circuit structure 300 may be in contact with the memory cell structure 400 through bonding pads BP1 and BP2.

The peripheral circuit structure 300 may include a core region or a peripheral circuit region of the DRAM device, and the memory cell structure 400 may include an array region of volatile memory cells of the DRAM device. For example, the peripheral circuit structure 300 may include peripheral circuit transistors PT1 and PT2 for transmitting signals and/or power to memory cell transistors included in the memory cell structure 400.

The peripheral circuit structure 300 may include a first substrate 310 where the trench isolation film STI is formed.

The first substrate 310 may include a wafer including Si. In some implementations, the first substrate 310 may include a wafer including a semiconductor element, such as Ge, or a compound semiconductor, such as SiC, GaAs, InAs, or InP.

The first substrate 310 may include a first substrate region 311 and a second substrate region 313. The first substrate region 311 and the second substrate region 313 may have different conductivity types. For example, the first substrate region 311 may include a p-well doped with p-type impurities, and the second substrate region 313 may include an n-well doped with n-type impurities. As another example, the first substrate region 311 may include an n-well doped with n-type impurities, and the second substrate region 313 may include a p-well doped with p-type impurities.

The first source/drain region SD1 may be formed in the first substrate region 311, and the second source/drain region SD2 may be formed in the second substrate region 313. The first source/drain region SD1 may constitute a portion of the first peripheral circuit transistor PT1 to be described below, and the second source/drain region SD2 may constitute a portion of the second peripheral circuit transistor PT2 to be described below.

The active region may be defined by the trench isolation film STI, which is an insulating region, in the first substrate 310. The trench isolation film STI may extend in the vertical direction D2 toward the inside of each of the first substrate region 311 and the second substrate region 313. The trench isolation film STI may be in contact with each of the first substrate region 311 and the second substrate region 313.

The first peripheral circuit transistor PT1 and the second peripheral circuit transistor PT2 may be disposed on the bottom surface of the first substrate 310. The first peripheral circuit transistor PT1 may be disposed on the bottom surface of the first substrate region 311, and the second peripheral circuit transistor PT2 may be disposed on the bottom surface of the second substrate region 313. In some implementations, each of the first peripheral circuit transistor PT1 and the second peripheral circuit transistor PT2 may be included in various circuits, such as a command decoder, a control logic, an address buffer, a row decoder, a column decoder, a sense amplifier, a data input/output circuit, and the like.

Each of the first peripheral circuit transistor PT1 and the second peripheral circuit transistor PT2 may include a gate dielectric film and a gate electrode stacked on the active region in this order. The gate dielectric film may be formed of at least one selected from silicon oxide, silicon nitride, silicon oxynitride, and a high dielectric material having a dielectric constant higher than that of silicon oxide. The gate electrode may include doped polysilicon, TiN, TiSiN, W, WSi, or a combination thereof. In some implementations, both sidewalls of the gate electrode may be covered with the gate spacer. The gate spacer may include silicon oxide, silicon nitride, or a combination thereof.

Each of the first peripheral circuit transistor PT1 and the second peripheral circuit transistor PT2 may include, for example, a GAAFET, an MBCFET, or a FinFET.

A first peripheral circuit insulating layer 321 may cover the first peripheral circuit transistor PT1 and the second peripheral circuit transistor PT2. The first peripheral circuit insulating layer 321 may be made of, for example, an oxide.

A first peripheral insulating layer 323 may be disposed on the bottom surface of the first peripheral circuit insulating layer 321. The first peripheral insulating layer 323 may surround the first bonding pad BP1. The first peripheral insulating layer 323 may be made of, for example, a nitride (e.g., silicon nitride).

The first peripheral circuit wiring layer 330 may be disposed on the bottom surface of the first substrate 310. The first peripheral circuit wiring layer 330 may include a first peripheral circuit via 331 and a first peripheral circuit line 333. The first peripheral circuit via 331 may penetrate the first peripheral circuit insulating layer 321 in the vertical direction D2. The first peripheral circuit via 331 may be in contact with the first source/drain region SD1 and the second source/drain region SD2. The first peripheral circuit via 331 may be connected to each of the first peripheral circuit transistor PT1 and the second peripheral circuit transistor PT2. The first peripheral circuit line 333 may be electrically connected to each of the first peripheral circuit transistor PT1 and the second peripheral circuit transistor PT2 through the first peripheral circuit via 331. In addition, the first peripheral circuit wiring layer 330 may be electrically connected to the first bonding pad BP1.

Each of the plurality of insulating structures BI may be aligned in the vertical direction D2 at the boundary between the first substrate region 311 and the second substrate region 313. The top surface of the insulating structure BI may be arranged at the same vertical level as the top surface of the first substrate 310. The bottom surface of the insulating structure BI may be arranged between a vertical level where the top surface of the trench isolation film STI is disposed and a vertical level where the top surfaces of the first and second substrate regions 311 and 313 are disposed. For example, the bottom surface of the insulating structure BI may be arranged at a vertical level higher than the top surface of the trench isolation film STI and may be arranged at a vertical level lower than the top surfaces of the first and second substrate regions 311 and 313.

Referring to FIG. 2B, a fourth length t4, which is a height of the insulating structure BI in the vertical direction D2, may be less than a third length t3, which is a length from the top surface of the first substrate 310 to the top surface of the trench isolation film STI. Although the plurality of insulating structures BI are shown in FIGS. 2A and 2B to have the same height, this is only an example, and their heights are not limited thereto. For example, the bottom surface of each of the plurality of insulating structures BI may be arranged at different vertical levels within a range that is greater than the vertical level of the top surface of the trench isolation film STI and less than the vertical level of the top surfaces of the first and second substrate regions 311 and 313. The top surfaces of the plurality of insulating structures BI may be coplanar with the top surface of the first substrate 310.

The plurality of insulating structures BI may have a tapered shape in which a cross-sectional area of the top surface is greater than that of the bottom surface, gradually narrowing

toward the bottom surface. This may be because the process of forming a hole for forming the plurality of insulating structures BI is a process of removing a portion of the first substrate 310 from the top surface of the first substrate 310. That is, since the trench isolation film STI and the plurality of insulating structures BI are formed when the top surface and the bottom surface of the first substrate 310 are opposite to each other, the cross-sectional area of the trench isolation film STI may increase in a direction away from the top surface of the first substrate 310, while the cross-section of the plurality of insulating structures BI may decrease in the direction away from the top surface of the first substrate 310.

In some implementations, the insulating structure BI may include an insulating material. For example, the insulating structure BI may include silicon oxide, but is not limited thereto.

A second peripheral circuit wiring layer 360 and a second peripheral circuit insulating layer 350 may be disposed on the top surface of the first substrate 310. The second peripheral circuit insulating layer 350 may cover the first substrate 310, the insulating structure BI, and the second peripheral circuit wiring layer 360. The second peripheral circuit insulating layer 350 may be made of, for example, an oxide.

The second peripheral circuit wiring layer 360 may include a second peripheral circuit via 361 and second peripheral circuit lines 363. The second peripheral circuit via 361 may electrically connect the second peripheral circuit lines 363 to each other. The second peripheral circuit line 363 may be electrically connected to the first peripheral circuit wiring layer 330 through a through via. The first peripheral circuit wiring layer 330 and the second peripheral circuit wiring layer 360 may be formed of, for example, a copper layer, an aluminum layer, or a tungsten layer.

The through via may electrically connect the first peripheral circuit wiring layer 330 to the second peripheral circuit wiring layer 360. The through via may include, for example, a through silicon via.

The memory cell structure 400 may include a second substrate 410. The material constituting the second substrate 410 may be substantially the same as the material constituting the first substrate 310 described above, and thus a detailed description thereof is omitted.

A laminated structure 450 may be disposed on the second substrate 410. The laminated structure 450 may include a plurality of insulating layers and a plurality of conductive lines alternately stacked. In some implementations, each of the plurality of insulating layers and the plurality of conductive lines may extend in the horizontal direction D1. The plurality of conductive lines may function as word lines of the memory cell structure 400.

In some implementations, the laminated structure 450 may further include a plurality of channel regions spaced apart from each other in the vertical direction D2. In addition, a cell wiring layer may be connected to the conductive line located at the top. The cell wiring layer may be formed of, for example, a copper layer, an aluminum layer, or a tungsten layer.

The memory cell transistor included in the memory cell structure 400 may include, for example, a buried channel array transistor (BACT), a VCT, or a 3D stacked transistor.

The cell wiring layer may be connected to the conductive line located at the top. The cell wiring layer may include a cell via and a cell line. The cell via may be in contact with the bottom surface of the second bonding pad BP2. The cell line may be electrically connected to the conductive line located at the top through the cell via. The second bonding pad BP2 may be surrounded by a second peripheral insulating layer 453.

In the semiconductor device 20, the peripheral circuit structure 300 and the memory cell structure 400 may form a bonding structure. In some implementations, the peripheral circuit structure 300 may be bonded to the memory cell structure 400 using a heat treatment process. The heat treatment process may be performed at a temperature where bonding coupling is formed between the first bonding pad BP1 of the peripheral circuit structure 300 and the second bonding pad BP2 of the memory cell structure 400. Accordingly, the first bonding pad BP1 and the second bonding pad BP2 may be bonded between the peripheral circuit structure 300 and the memory cell structure 400. Each of the first bonding pad BP1 and the second bonding pad BP2 may include, for example, a copper layer. In this case, the adhesive bonding between the first bonding pad BP1 and the second bonding pad BP2 may be performed by Cu-Cu hybrid bonding.

As described with reference to FIGS. 1A and 1B, the insulating structure BI of the semiconductor device 20 may be arranged between the first substrate region 311 and the second substrate region 313 to prevent the leakage of current between the first substrate region 311 and the second substrate region 313. The semiconductor device 30 may form the insulating structure BI to a depth such that the insulating structure BI is not in contact with the trench isolation film STI, or is spaced apart from the trench isolation film STI, thereby reducing the difficulty of the process of forming the insulating structure BI and preventing the electrical characteristics of the first and/or second peripheral circuit transistors TR1 and/or TR2 from being deteriorated.

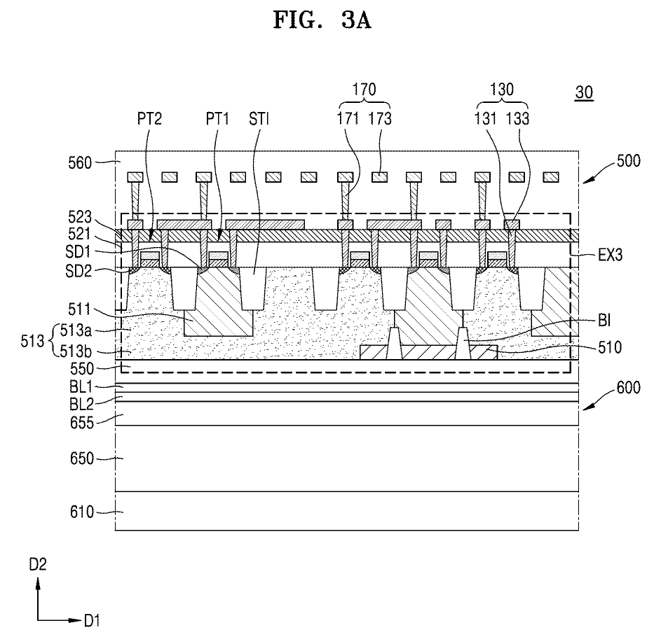

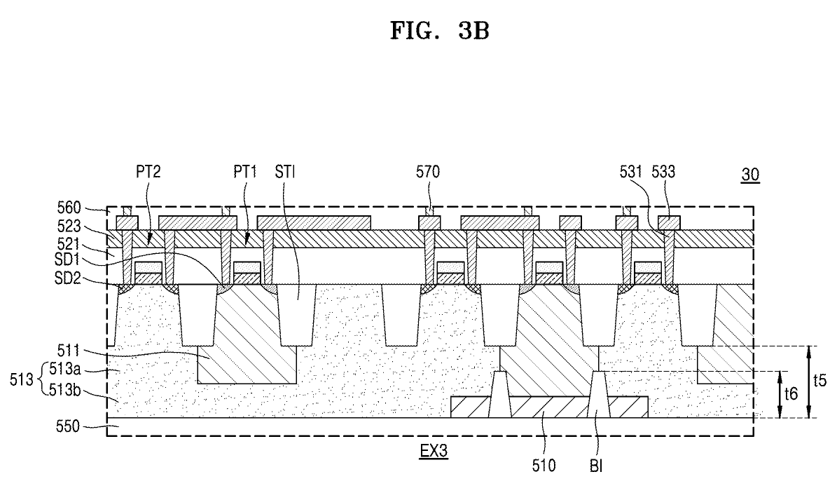

FIG. 3A is a cross-sectional view of another example of a semiconductor device 30. FIG. 3B is an enlarged cross-sectional view of portion EX3 of FIG. 3A.

Since the configuration of the semiconductor device 30 described with reference to FIGS. 3A and 3B is similar to that of the semiconductor device 10 described with reference to FIGS. 1A and 1B, the differences are mainly described below.

Referring to FIGS. 3A and 3B, a first substrate 510 may include a first substrate region 511 and a second substrate region 513, wherein the second substrate region 513 may include an upper second substrate region 513a and a lower second substrate region 513b. The upper second substrate region 513a and the lower second substrate region 513b may have the same conductivity type, and the first substrate region 511 and the second substrate region 513 may have different conductivity types. For example, the first substrate region 511 may include a p-well doped with p-type impurities, and the second substrate region 513 may include an n-well doped with n-type impurities. As another example, the first substrate region 511 may include a n-well doped with n-type impurities, and the second substrate region 513 may include a p-well doped with p-type impurities.

The first source/drain region SD1 may be formed in the first substrate region 511 and the second source/drain region SD2 may be formed in the upper second substrate region 513a. The first source/drain region SD1 may constitute a portion of the first peripheral circuit transistor PT1 to be described below, and the second source/drain region SD2 may constitute a portion of the second peripheral circuit transistor PT2 to be described below.

The lower second substrate region 513b may be arranged between the lower insulating layer 550 and the first substrate region 511 and between the lower substrate insulating layer 550 and an upper second substrate region 513a. In some implementations, the upper and lower second substrate regions 513a and 513b may be connected to each other.

The active region may be defined by the trench isolation film STI, which is an insulating region, in the first substrate 510. The trench isolation film STI may extend in the vertical direction D2 toward the inside of each of the first substrate region 511 and the upper second substrate region 513a. The trench isolation film STI may be in contact with each of the first substrate region 511 and the upper second substrate region 513a.

The lower second substrate region 513b may be formed by forming the first substrate region 511 and the upper second substrate region 513a in the first substrate 510, and then forming a well of the same conductivity type as the upper second substrate region 513a below the first substrate region 511 and the upper second substrate region 513a by using an ion implantation process.

In some implementations, the lower second substrate region 513b may include a conductive region formed to surround the first substrate region 511 with a conductivity type opposite to that of the first substrate region 511. When the semiconductor device 30 includes the lower second substrate region 513b, some of the plurality of first substrate regions 511 of which entire surface is surrounded by the second substrate region 513 do not need to have the insulating structure BI arranged at the boundary of some of the first substrate regions 511. Thus, the insulating structure BI may be formed only at the boundary of the other first substrate regions 511 than some of the first substrate regions 511. Therefore, in some implementations, unlike the semiconductor device 10 of FIGS. 1A and 1B, the semiconductor device 30 of FIGS. 3A and 3B may include the insulating structure BI only at a portion of the boundary between the first substrate region 511 and the upper second substrate region 513a.

Each of the plurality of insulating structures BI may be aligned in the vertical direction D2 at the boundary between the first substrate region 511 and the upper second substrate region 513a. The bottom surface of the insulating structure BI may be arranged at the same vertical level as the bottom surface of the first substrate 510. The top surface of the insulating structure BI may be arranged between the vertical level where the bottom surfaces of the first substrate region 511 and the upper second substrate region 513a are disposed and the vertical level where the bottom surface of the trench isolation film STI is disposed. For example, the top surface of the insulating structure BI may be arranged at a vertical level higher than the bottom surfaces of the first substrate region 511 and the upper second substrate region 513a and may be arranged at a vertical level lower than the bottom surface of the trench isolation film STI.

Referring to FIG. 3B, a sixth length t6, which is a height of the insulating structure BI in the vertical direction D2, may be less than a fifth length t5, which is a length from the bottom surface of the first substrate 510 to the bottom surface of the trench isolation film STI. In FIGS. 3A and 3B, the plurality of insulating structures BI are shown to have the same height, but their heights are not limited thereto. For example, the top surface of each of the plurality of insulating structures BI may be arranged at different vertical levels within a range that is greater than the vertical level of the top surfaces of the first substrate region 511 and the upper second substrate region 513a and less than the vertical level of the bottom surface of the trench isolation film STI. The bottom surfaces of the plurality of insulating structures BI may be coplanar with the bottom surface of the first substrate 510.

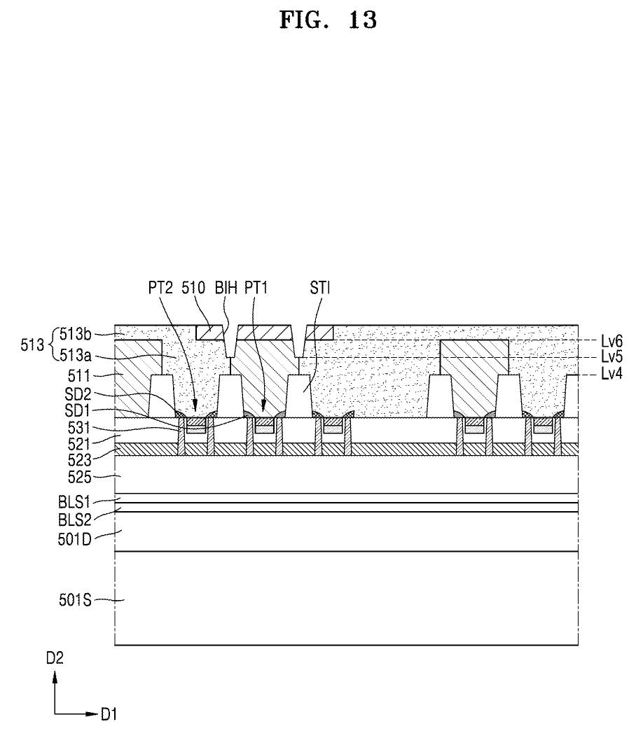

The plurality of insulating structures BI may have a tapered shape in which a cross-sectional area of the bottom surface is greater than that of the top surface, gradually narrowing toward the top surface. This may include a profile obtained by flipping the first substrate 510 such that the bottom surface of the first substrate 510 becomes the top surface thereof before performing the process of forming the plurality of insulating structure holes BIH (see FIG. 13). For example, the cross-sectional area of the trench isolation film STI may increase in a direction away from the bottom surface of the first substrate 510, while the cross-section of the plurality of insulating structures BI may decrease in the direction away from the bottom surface of the first substrate 510.

As described above, the semiconductor device 30 separates the boundary between the first substrate region 511 and the upper second substrate region 513a within a range in which the insulating structure BI is not in contact with the trench isolation film STI, thereby effectively preventing the leakage of current between wells without affecting the electrical reliability of the first and/or second peripheral circuit transistors PT1 and/or PT2. In addition, since the insulating structure BI is not formed deeper than necessary, the process of filling the insulating structure hole BIH (see FIG. 13) with the insulating structure BI may be relatively easy.

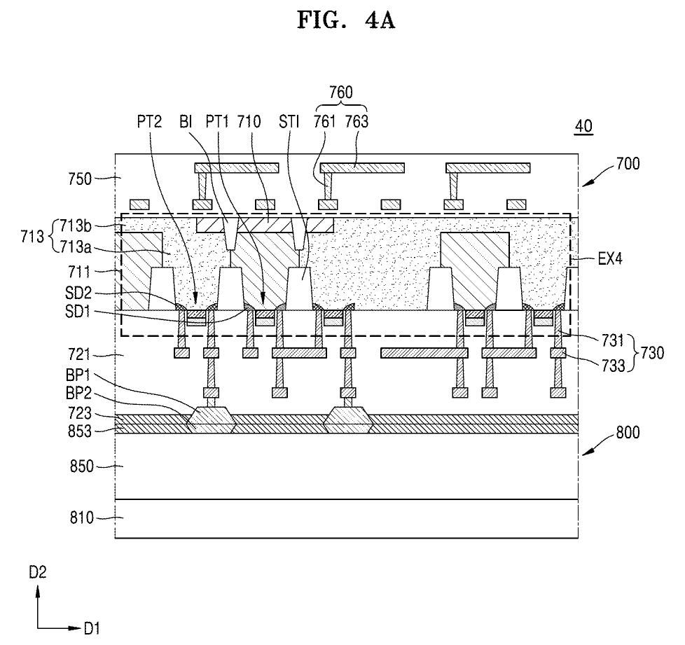

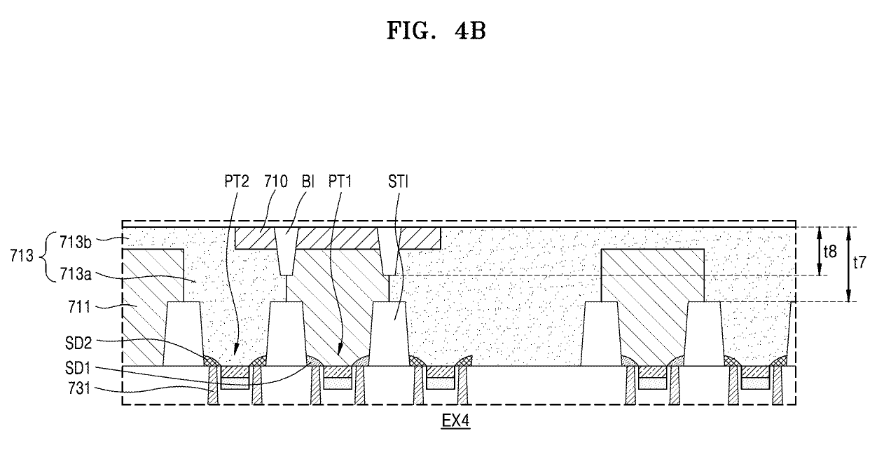

FIG. 4A is a cross-sectional view of another example of a semiconductor device 40. FIG. 4B is an enlarged cross-sectional view of portion EX4 of FIG. 4A.

Since the configuration of the semiconductor device 40 described with reference to FIGS. 4A and 4B is similar to that of the semiconductor device 20 described with reference to FIGS. 2A and 2B, the differences are mainly described below.

Referring to FIGS. 4A and 4B, a first substrate 710 may include a first substrate region 711 and a second substrate region 713, wherein the second substrate region 713 may include a lower second substrate region 713a and an upper second substrate region 713b. The lower second substrate region 713a and the upper second substrate region 713b may have the same conductivity type, and the first substrate region 711 and the second substrate region 713 may have different conductivity types. For example, the first substrate region 711 may include a p-well doped with p-type impurities, and the second substrate region 713 may include an n-well doped with n-type impurities. As another example, the first substrate region 711 may include a n-well doped with n- type impurities, and the second substrate region 713 may include a p-well doped with p-type impurities.

The first source/drain region SD1 may be formed in the first substrate region 711, and the second source/drain region SD2 may be formed in the lower second substrate region 713a. The first source/drain region SD1 may constitute a portion of the first peripheral circuit transistor PT1 to be described below, and the second source/drain region SD2 may constitute a portion of the second peripheral circuit transistor PT2 to be described below.

The upper second substrate region 713b may be arranged between the second peripheral circuit insulating layer 750 and the first substrate region 711 and between the second peripheral circuit insulating layer 750 and the lower second substrate region 713a. In some implementations, the lower and upper second substrate regions 713a and 713b may be connected to each other.

The active region may be defined by the trench isolation film STI, which is an insulating region, in the first substrate 710. The trench isolation film STI may extend in the vertical direction D2 toward the inside of each of the first substrate region 711 and the lower second substrate region 713a. The trench isolation film STI may be in contact with each of the first substrate region 711 and the lower second substrate region 713a.

The upper second substrate region 713b may be formed by forming the first substrate region 711 and the lower second substrate region 713a in the first substrate 710, and then forming a well of the same conductivity type as the lower second substrate region 713a below the first substrate region 711 and the lower second substrate region 713a by using an ion implantation process.

In some implementations, the upper second substrate region 713b may include a conductive region formed to surround the first substrate region 711 with a conductivity type opposite to that of the first substrate region 711. When the semiconductor device 40 includes the upper second substrate region 713b, some of the plurality of first substrate regions 711 of which entire surface is surrounded by the second substrate region 713 do not need to have the insulating structure BI arranged at the boundary of some of the first substrate regions 711. Thus, the insulating structure BI may be formed only at the boundary of the other first substrate regions 711 than some of the first substrate regions 711. Therefore, in some implementations, unlike the semiconductor device 20 of FIGS. 2A and 2B, the semiconductor device 40 of FIGS. 4A and 4B may include the insulating structure BI only at a portion of the boundary between the first substrate region 711 and the lower second substrate region 713a.

Each of the plurality of insulating structures BI may be aligned in the vertical direction D2 at the boundary between the first substrate region 711 and the lower second substrate region 713a. The top surface of the insulating structure BI may be arranged at the same vertical level as the top surface of the first substrate 710. The bottom surface of the insulating structure BI may be arranged between the vertical level where the top surfaces of the first substrate region 711 and the lower second substrate region 713a are disposed and the vertical level where the top surface of the trench isolation film STI is disposed. For example, the bottom surface of the insulating structure BI may be arranged at a lower vertical level than the top surfaces of the first substrate region 711 and the lower second substrate region 713a and may be arranged at a higher vertical level than the top surface of the trench isolation film STI.

Referring to FIG. 4B, an eighth length t8, which is a height of the insulating structure BI in the vertical direction D2, may be less than a seventh length t7, which is a length from the top surface of the first substrate 710 to the top surface of the trench isolation film STI. In FIGS. 4A and 4B, a plurality of insulating structures BI are shown to have the same height, but their heights are not limited thereto. For example, the bottom surface of each of the plurality of insulating structures BI may be arranged at different vertical levels within a range that is greater than the vertical level of the top surface of the trench isolation film STI and less than the vertical level of the top surfaces of the first substrate region 711 and the lower second substrate region 713a. The top surfaces of the plurality of insulating structures BI may be coplanar with the bottom surface of the first substrate 710.

The plurality of insulating structures BI may have a tapered shape in which a cross-sectional area of the top surface is greater than that of the bottom surface, gradually narrowing toward the bottom surface. This may be because the process of forming a hole for forming the plurality of insulating structures BI is a process of removing a portion of the first substrate 710 from the top surface of the first substrate 710. For example, since the trench isolation film STI and the plurality of insulating structures BI are formed when the top surface and the bottom surface of the first substrate 710 are opposite to each other, the cross-sectional area of the trench isolation film STI may increase in a direction away from the top surface of the first substrate 710, while the cross-section of the plurality of insulating structures BI may decrease in the direction away from the top surface of the first substrate 710.

In some implementations, the insulating structure BI may include an insulating material. For example, the insulating structure BI may include silicon oxide, but is not limited thereto.

As described above with reference to the semiconductor devices 10, 20, and 30, the insulating structure BI of the semiconductor device 40 may be arranged between the first substrate region 711 and the lower second substrate region 713a to prevent the leakage of current between the first substrate region 711 and the lower second substrate region 713a. The semiconductor device 40 may form the insulating structure BI to a depth not in contact with the trench isolation film STI, thereby reducing the difficulty of the process of forming the insulating structure BI and preventing the electrical characteristics of the first and/or second peripheral circuit transistors TR1 and/or TR2 from being deteriorated. In addition, in a case in which some of the first substrate regions 711 have an entire surface covered by the second substrate region 713, the insulating structure BI may be omitted at the boundary between the second substrate region 713 and some of the first substrate regions 711.

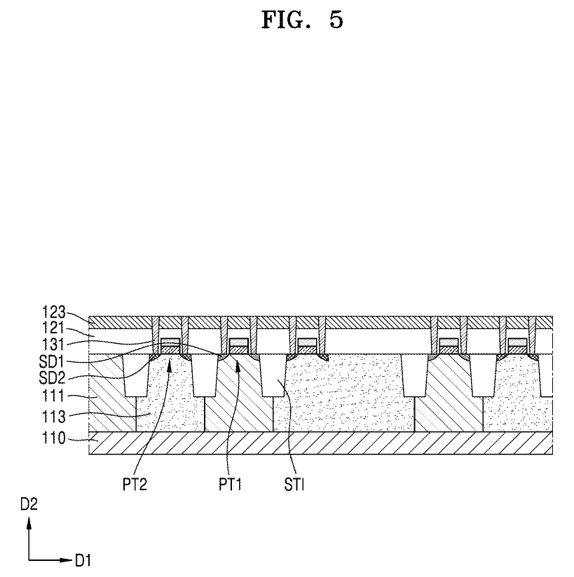

FIGS. 5 to 9 are cross-sectional views illustrating an example of a method of manufacturing the semiconductor device 10.

Referring to FIG. 5, a structure in which the peripheral circuit transistors PT1 and PT2, the first and second source/drain regions SD1 and SD2, the first peripheral circuit insulating layer 121, and the interlayer insulating layer 123 are formed on the first substrate 110 may be provided. In FIG. 5, the first substrate 110 may include the first substrate region 111 and the second substrate region 113, wherein the second substrate region 113 may be covered by the first substrate region 111. The first substrate 110 may further include the trench isolation film STI extending from the top surface of the first substrate 110 to a predetermined depth toward the inside of the first substrate 110 at the boundary between the first substrate region 111 and the second substrate region 113.

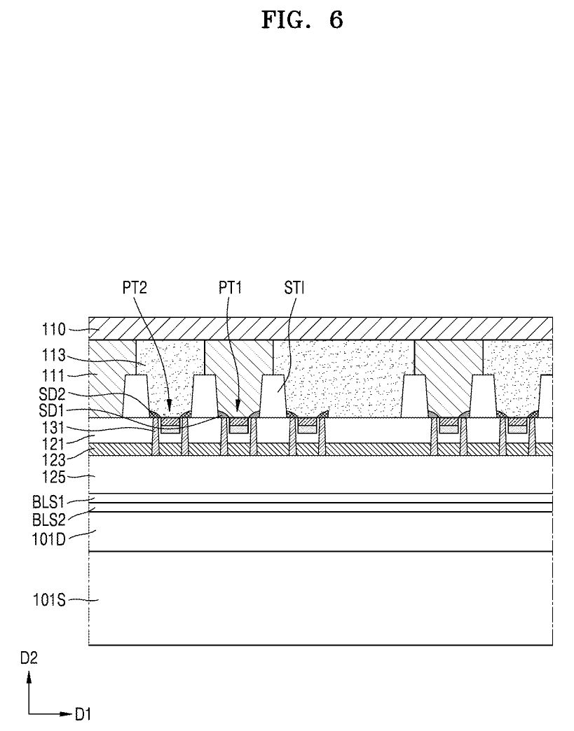

Next, referring to FIG. 6, a handler 101S may be attached to the result of FIG. 5, and the result of the FIG. 5 to which the handler 101S is attached may be flipped. To attach the handler 101S to the result of FIG. 5, an insulating layer 125 and a first adhesive insulating layer BLS1 may be formed on the interlayer insulating layer 123, and the handler 101S on which a handler insulating layer 101D and a second adhesive insulating layer BLS2 are sequentially formed may be attached to the result of FIG. 5. In some implementations, the attachment may be performed by adhesive bonding between an insulating material forming the first adhesive insulating layer BLS1 and an insulating material forming the second adhesive insulating layer BLS2.

Referring to FIG. 7, from the structure of FIG. 6, the first substrate 110 may be thinned by removing a portion of the first substrate 110. By removing a portion of the first substrate 110, the thickness of the first substrate 110 in the vertical direction D2 may be reduced.

Next, the insulating structure hole BIH may be formed. As shown in FIG. 7, the insulating structure hole BIH may be formed in a tapered shape where the width decreases vertically downward. The insulating structure hole BIH may be formed at a depth that separates the upper portions of the first substrate region 111 and the second substrate region 113 from each other in the vicinity of the boundary between the first substrate region 11 and the second substrate region 113.

In some implementations, a position where the insulating structure hole BIH is formed may vertically overlap a position where the trench isolation film STI is formed. The vertical level of the bottom surface of the insulating structure hole BIH may be formed to an extent that the trench isolation film STI is not exposed. That is, when the vertical level at which the top surface of the trench isolation film STI is arranged is defined as a first level Lv1, and the vertical level at which the top surfaces of the first substrate region 111 and the second substrate region 113 are arranged is defined as a third level Lv3, a second level Lv2, which is the vertical level at which the bottom surface of the insulating structure hole BIH is arranged, may include a position higher than the first level Lv1 and lower than the third level Lv3. This may cause the insulating structure BI (see FIG. 8) filling the insulating structure hole BIH to separate the first substrate region 111 and the second substrate region 113 in a subsequent process, thereby blocking the leakage current between the first substrate region 111 and the second substrate region 113 while preventing the physical contact between the insulating structure BI and the trench isolation film STI.

Referring to FIG. 8, the insulating structure BI filling the insulating structure hole BIH may be formed. The insulating structure BI may include, for example, an oxide, but is not limited thereto. The trench isolation film STI may have a tapered shape where the width of the trench isolation film STI decreases away from the handler 101S while the insulating structure BI may have a tapered shape where the width of the insulating structure BI decreases towards the handler 101S. The difference in the sidewall profile of the insulating structure BI and the trench isolation

film STI may be a result of flipping the first substrate 110 (see FIG. 6) after forming the trench isolation film STI and before forming the insulating structure BI.

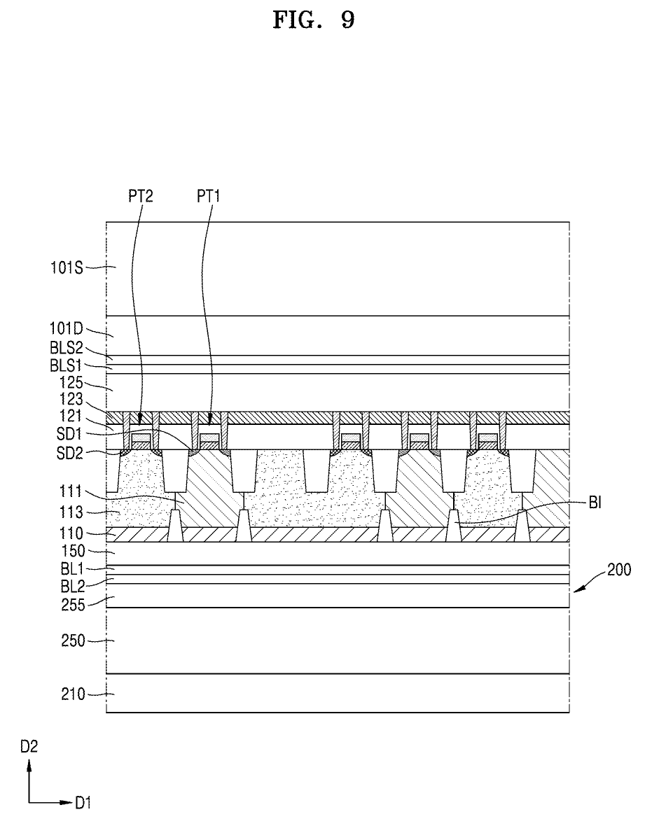

Referring to FIG. 9, the lower insulating layer 150 covering the first substrate 110 may be formed on the result of FIG. 8, and the first bonding insulating layer BL1 may be formed on the lower insulating layer 150. Next, the resulting structure in which the lower insulating layer 150 and the first dividing insulating layer BL1 are formed may be flipped and then attached onto the provided memory cell structure 200. The attachment may be performed by adhesive bonding between an insulating material forming the first bonding insulating layer BL1 and an insulating material forming the second bonding insulating layer BL2.

In FIG. 9, the semiconductor device 10 described with reference to FIGS. 1A and 1B may be formed by removing the handler 101S, the handler insulating layer 101D, and the second adhesive insulating layer BLS2, forming the first peripheral circuit via 131 and the through via on the interlayer insulating layer 123, and forming the second peripheral circuit wiring layer 170 and the second peripheral circuit insulating layer 160.

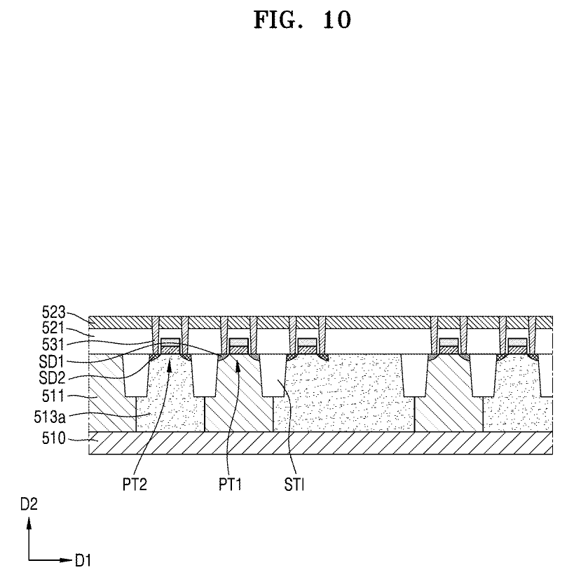

FIGS. 10 to 15 are cross-sectional views illustrating an example of a method of manufacturing the semiconductor device 30.

Referring to FIG. 10, a structure in which the peripheral circuit transistors PT1 and PT2, the first and second source/drain regions SD1 and SD2, a first peripheral circuit insulating layer 521, and an interlayer insulating layer 523 are formed on a first substrate 510 may be provided. In FIG. 10, the first substrate 510 may include a first substrate region 511 and an upper second substrate region 513a, wherein the upper second substrate region 513a may be covered by the first substrate region 511. The first substrate 510 may further include the trench isolation film STI extending from the top surface of the first substrate 510 to a predetermined depth toward the inside of the first substrate 510 at the boundary between the first substrate region 511 and the upper second substrate region 513a.

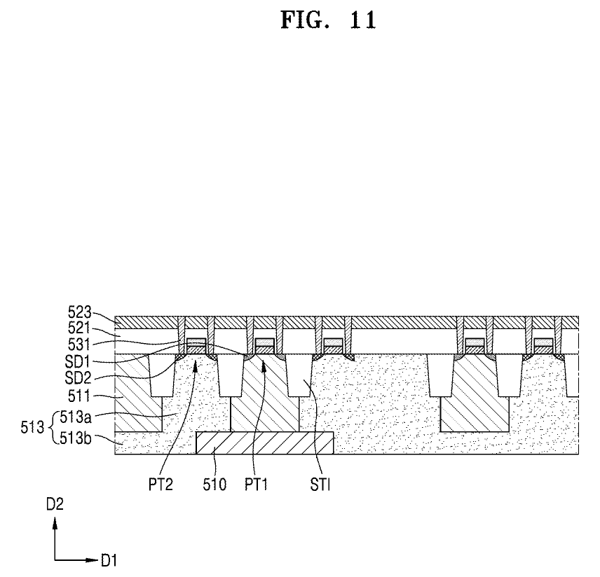

Referring to FIG. 11, the lower second substrate region 513b may be formed below the first substrate region 511 and the upper second substrate region 513a. In some implementations, the lower second substrate region 513b may be formed by implanting a dopant into at least a part of lower portions of the first substrate region 511 and the upper second substrate region 513a using an ion implantation process. The lower second substrate region 513b may be substantially connected to the upper second substrate region 513a.

As shown in FIG. 11, some of the plurality of first substrate regions 511 may be surrounded on all sides by the lower second substrate region 513b and the upper second substrate region 513a.

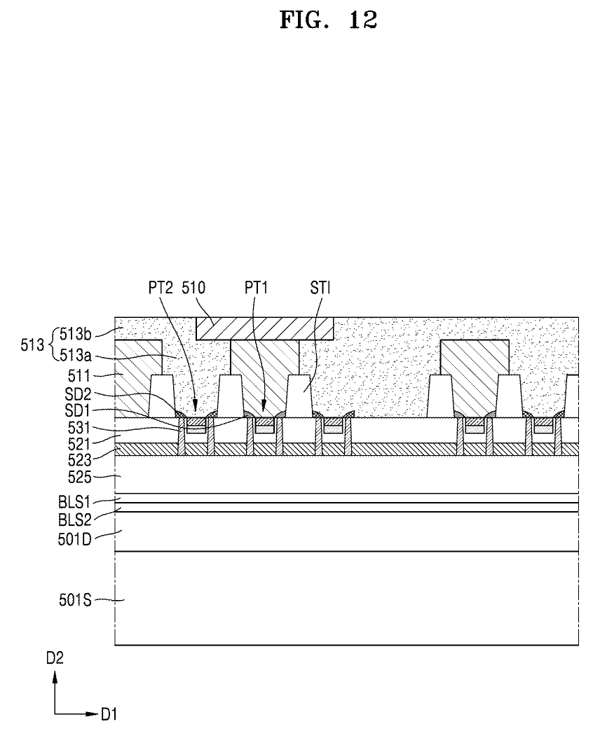

Referring to FIG. 12, a handler 501S may be attached to the result of FIG. 11, and the result of the FIG. 11 to which the handler 501S is attached may be flipped. Through this process, the upper second substrate region 513a may be disposed vertically below the lower second substrate region 513b. To attach the handler 501S to the result of FIG. 11, an insulating layer 525 and the first adhesive insulating layer BLS1 may be formed on the interlayer insulating layer 523, and the handler 501S on which the handler insulating layer 501D and the second adhesive insulating layer BLS2 are sequentially formed may be attached to the result of FIG. 11. In some implementations, the attachment may be performed by adhesive bonding between an insulating material forming the first adhesive insulating layer BLS1 and an insulating material forming the second adhesive insulating layer BLS2.

Referring to FIG. 13, from the structure of FIG. 12, the first substrate 510 may be thinned by removing a portion of the first substrate 510. By removing a portion of the first substrate 510, the thickness of the first substrate 310 may be reduced in the vertical direction D2.

Next, the insulating structure hole BIH may be formed. As shown in FIG. 13, the insulating structure hole BIH may be formed in a tapered shape in which the width thereof decreases vertically downward. The insulating structure hole BIH may extend across the lower second substrate region 513b and may be formed to have a depth that separates the upper portions of the first substrate region 511 from the upper second substrate region 513a near the boundary between the first substrate region 511 and the upper second substrate region 513a.

In some implementations, a position where the insulating structure hole BIH is formed may vertically overlap a position where the trench isolation film STI is formed. The vertical level of the bottom surface of the insulating structure hole BIH may be formed to such an extent that the trench isolation film STI is not exposed. In other words, when the vertical level at which the top surface of the trench isolation film STI is disposed is defined as a fourth level Lv4 and the vertical level at which the top surfaces of the first substrate region 511 and the upper second substrate region 513a are disposed is defined as a sixth level Lv6, a fifth level Lv5, which is a vertical level at which the bottom surface of the insulating structure hole BIH is disposed, may include a position higher than the fourth level Lv4 and lower than the sixth level Lv6. This may cause the insulating

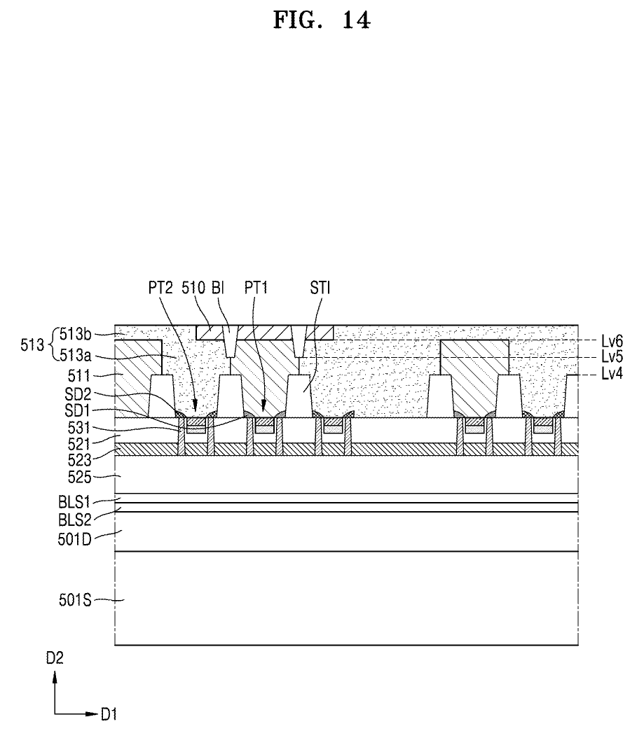

structure BI (see FIG. 14) filling the insulating structure hole BIH in a subsequent process to separate the first substrate region 511 from the upper second substrate region 513a, thereby blocking the leakage current between the first substrate region 511 and the upper second substrate region 513a, while preventing the physical contact between the insulating structure BI and the trench isolation film STI.

Referring again to FIG. 13, each of the plurality of insulating structure holes BIH may be formed at the position overlapping the trench isolation film STI in the vertical direction D2, but the plurality of insulating structure holes BIH are not formed on all the trench isolation films STI. This may be because, as described with reference to FIG. 11, some of the plurality of first substrate regions 511 are surrounded on all sides by the upper second substrate region 513a and the lower second substrate region 513b, and thus, the structure for preventing the leakage current at the boundary between the first substrate region 511 and neighboring upper second substrate regions 513a is not required.

Referring to FIG. 14, the insulating structure BI filling the insulating structure hole BIH may be formed. The insulating structure BI may include, for example, an oxide, but is not limited thereto. The trench isolation film STI may have a tapered shape where the width of the trench isolation film STI decreases away from the handler 501S, while the insulating structure BI may have a tapered shape where the width of the insulating structure BI decreases towards the handler 501S. The difference in the sidewall profile of the insulating structure BI and the trench isolation film STI may be a result of flipping the first substrate 510 (see FIG. 12) after forming the trench isolation film STI and before forming the insulating structure BI.

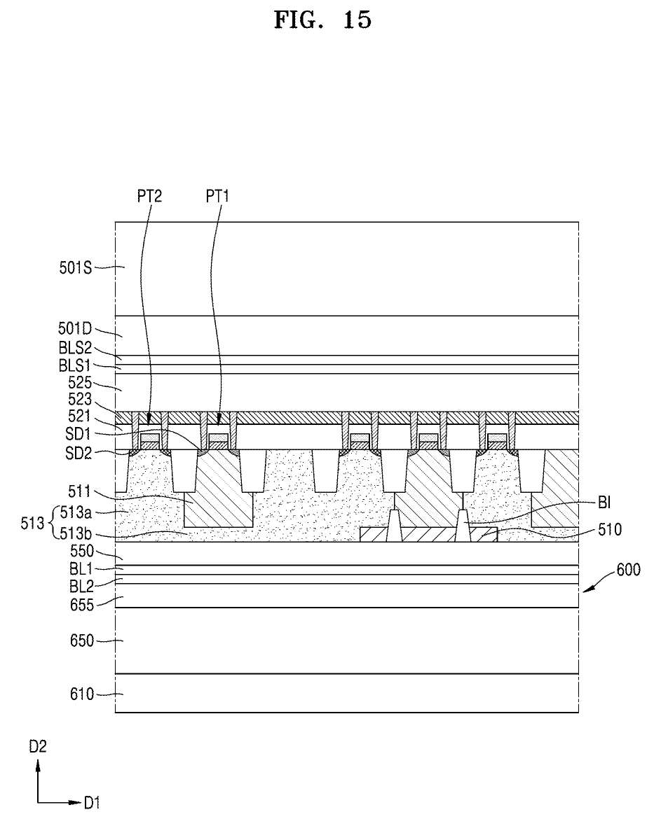

Referring to FIG. 15, the lower insulating layer 550 covering the first substrate 510 may be formed on the result of FIG. 14, and the first bonding insulating layer BL1 may be formed on the lower insulating layer 550. Next, the resulting structure in which the lower insulating layer 550 and the first dividing insulating layer BL1 are formed may be flipped, and the result may be attached onto a provided memory cell structure 600. The attachment may be performed by adhesive bonding between an insulating material forming the first bonding insulating layer BL1 and an insulating material forming the second bonding insulating layer BL2.

In FIG. 15, the semiconductor device 30 described with reference to FIGS. 3A and 3B may be formed by removing the handler 501S, the handler insulating layer 501D, and the second adhesive insulating layer BLS2, forming the first peripheral circuit via 531 and through via on the interlayer insulating layer 523, and forming the second peripheral circuit wiring layer 570 and the second peripheral circuit insulating layer 560.

Herein, a peri-on-cell structure in which the peripheral circuit structures 100, 300, 500, and 700 are stacked on top of the memory cell structures 200, 400, 600, and 800, respectively, is shown, but structures within the scope of this disclosure are not limited thereto. For example, the configurations described herein may also be applied to a cell-on-peri structure in which the memory cell structures 200, 400, 600, and 800 are stacked on top of the peripheral circuit structures 100, 300, 500, and 700, respectively.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. Operations in the drawings may be performed in a different order to that illustrated.

While certain examples have been particularly shown and described, it will be understood that various changes in form and details may be made therein without departing from the spirit and scope of this disclosure.

What is claimed is:

1. A semiconductor device comprising:
a peripheral circuit structure, the peripheral circuit structure comprising:
a first substrate comprising a first substrate region and a second substrate region having different conductivity types, wherein the first substrate comprises a first surface and a second surface opposing the first surface along a vertical direction;
a trench isolation film extending in the vertical direction from the first surface of the first substrate toward the second surface of the first substrate; and
an insulating structure extending in the vertical direction from the second surface of the first substrate toward the first surface of the first substrate, wherein the insulating structure is in contact with each of the first substrate region and the second substrate region, and
wherein the insulating structure is spaced apart from the trench isolation film.

2. The semiconductor device of claim 1, wherein the insulating structure overlaps the trench isolation film along the vertical direction.

3. The semiconductor device of claim 1, wherein the trench isolation film comprises a first film surface arranged at a same vertical level as the first surface of the first substrate, and a second film surface opposing the first film surface along the vertical direction, and
wherein a height of the insulating structure in the vertical direction is less than a distance from the second surface of the first substrate to the second film surface of the trench isolation film.

4. The semiconductor device of claim 1, wherein the insulating structure has a tapered shape in which a width of the insulating structure decreases towards the trench isolation film.

5. The semiconductor device of claim 1, wherein the trench isolation film is between a source/drain region of a first transistor of the peripheral circuit structure and a source/drain region of a second transistor of the peripheral circuit structure.

6. The semiconductor device of claim 1, comprising a memory cell structure on the peripheral circuit structure.

7. The semiconductor device of claim 6, comprising bonding insulating layers between the memory cell structure and the peripheral circuit structure,
wherein the memory cell structure and the peripheral circuit structure are bonded by adhesive bonding between the bonding insulating layers.

8. The semiconductor device of claim 6, comprising bonding pads between the memory cell structure and the peripheral circuit structure,
wherein the memory cell structure and the peripheral circuit structure are bonded by bonding between the bonding pads.

9. The semiconductor device of claim 6, comprising a through via electrically connecting the memory cell structure to the peripheral circuit structure.

10. The semiconductor device of claim 1, wherein the trench isolation film has a tapered shape in which a width of the trench isolation film decreases towards the insulating structure.

11. A semiconductor device comprising:
a memory cell structure,
a peripheral circuit structure, and
through vias electrically connecting the memory cell structure to the peripheral circuit structure,
wherein the peripheral circuit structure comprises:
a first substrate comprising a first substrate region and a second substrate region having different conductivity types, wherein the first substrate comprises a first surface and a second surface opposing the first surface along a vertical direction,
wherein the second substrate region comprises a third substrate region arranged at a same vertical level as the first substrate region, and a fourth substrate region between the first substrate region and the second surface of the first substrate;
a plurality of trench isolation films extending in the vertical direction from the first surface of the first substrate toward the second surface of the first substrate;
a peripheral circuit transistor on the first substrate region and the third substrate region;
a peripheral circuit wiring layer electrically connected to the peripheral circuit transistor; and
a plurality of insulating structures extending in the vertical direction from the second surface of the first substrate toward the first surface of the first substrate,
wherein the first substrate region comprises a portion that is spaced apart from the plurality of insulating structures and in contact with a first trench isolation film of the plurality of trench isolation films.

12. The semiconductor device of claim 11, wherein the fourth substrate region is connected to the third substrate region, and wherein the third substrate region is on opposite lateral sides of the portion of the first substrate region.

13. The semiconductor device of claim 11, wherein the plurality of insulating structures comprise a first insulating structure that overlaps a second trench isolation film of the plurality of trench isolation films in the vertical direction.

14. The semiconductor device of claim 11, wherein the plurality of trench isolation films comprise a first film surface arranged at a same vertical level as the first surface of the first substrate, and a second film surface opposing the first film surface in the vertical direction, and
wherein a height of the plurality of insulating structures in the vertical direction is less than a distance from the second surface of the first substrate to the second film surface of the plurality of trench isolation films.

15. The semiconductor device of claim 11, wherein the plurality of insulating structures have a tapered shape in which a width of the plurality of insulating structures decreases towards the first surface of the first substrate, and the plurality of trench isolation films have a tapered shape in which a width of the plurality of trench isolation films decreases towards the second surface of the first substrate.

16. The semiconductor device of claim 11, wherein a second portion of the first substrate region is in contact with insulating structures of the plurality of insulating structures on opposite lateral sides.

17. A semiconductor device comprising:
a memory cell structure,
a peripheral circuit structure on the memory cell structure, and
through vias electrically connecting the memory cell structure to the peripheral circuit structure,
wherein the peripheral circuit structure comprises:
a first substrate comprising a first substrate region and a second substrate region having different conductivity types, wherein the first substrate comprises a first surface and a second surface opposing the first surface in a vertical direction;
a peripheral circuit transistor on the first substrate region and the second substrate region;
a peripheral circuit wiring layer electrically connected to the peripheral circuit transistor;
a trench isolation film extending in the vertical direction from the first surface of the first substrate toward the second surface of the first substrate, wherein the trench isolation film is in contact with each of the first substrate region and the second substrate region; and
an insulating structure extending in the vertical direction from the second surface of the first substrate toward the first surface of the first substrate, wherein the insulating structure is in contact with each of the first substrate region and the second substrate region,
wherein a first surface of the insulating structure is arranged at a same vertical level as the second surface of the first substrate, and wherein a height of the insulating structure is less than a distance from the first surface of the insulating structure to the trench isolation film in the vertical direction.

18. The semiconductor device of claim 17, wherein the insulating structure is overlaps the trench isolation film along the vertical direction.

19. The semiconductor device of claim 17, wherein the insulating structure has a tapered shape in which a width of the insulating structure decreases towards the trench isolation film, and the trench isolation film has a tapered shape in which a width of the trench isolation film decreases towards the insulating structure.

20. The semiconductor device of claim 17, wherein the second substrate region is between a portion of the first substrate region and the second surface of the first substrate,
wherein the semiconductor device comprises a plurality of trench isolation films including the trench isolation film,
wherein the semiconductor device comprises a plurality of insulating structures including the insulating structure,
wherein the plurality of insulating structures comprises a second insulating structure in contact with the portion of the first substrate region, and
wherein the portion of the first substrate region is spaced apart from the plurality of insulating structures.
